(19) United States
(12) Patent Application Publication
(10) Pub. No.: US 2013/0333740 A1
(43) Pub. Date: Dec. 19, 2013

(54) BUILDING SOLARROOF AND GREENHOUSE SOLARROOF

(71) Applicant: George Philip Tharisayi, Berkeley, CA (US)

(72) Inventor: George Philip Tharisayi, Berkeley, CA (US)

(21) Appl. No.: 13/845,813

(22) Filed: Mar. 18, 2013

Related U.S. Application Data
(60) Provisional application No. 61/689,787, filed on Jun. 13, 2012.

(51) Int. Cl. H01L 31/048; H01L 31/058

(52) U.S. Cl. CPC H01L 31/0482; H01L 31/058
USPC 136/244

(57) ABSTRACT

A building integrated solar thermal electric hybrid roofing system is disclosed to include a plurality of solar cell assemblies disposed on a solar exposed roof structure of a building. Each of the solar cell assembly generates DC electricity when a portion of solar energy is impacted on the solar cell assembly. The solar exposed roof structure is designed in such a manner that the solar exposed roof structure may or may not allow the portion of the impacted solar energy to be transmitted within a receiving zone of the building. A plurality of supporting members are also positioned at predefined locations on the roof supporting structure, wherein each of the supporting member is attachable to a corresponding solar cell assembly for supporting thereof on the solar exposed roof structure. DC electricity is used directly or a power inverter is connected to each or group of the solar cell assemblies for converting DC electricity into AC electricity.

### BACKGROUND

1. Field of the Invention

The present invention generally relates to a building integrated hybrid roofing system, and more particularly to an optimized building integrated hybrid roofing system that utilizes integrated solar thermal system for generation of solar thermal energy and photovoltaic system for generation of solar electricity.

2. Description of the Related Art

Search for solutions in relation to global warming and its potential consequences have been ongoing for some good years now. One of the ways to reduce the danger of global warming is to look for renewable energy sources as an alternative to conventional energy resources. Solar energy, as an example of renewable energy resources, is quite well known, environmental friendly and could be used as an alternative at much lesser cost than most of the conventional energy resources. Solar thermal energy and solar photovoltaic (PV) are the two most common and widely used technologies in terms of solar energy.

Solar thermal energy, especially in the form of solar collectors installed on roofs of buildings for the purposes of generating steam is well known. Similarly, it is also well known to use solar radiation for the purpose of generating space heating like heating interior of buildings. Though some of the space heating means and mechanisms are well known, they do not find much acceptability either because of their installation costs or because of their complexity. Also well known in the art is to provide photovoltaic cells for generation of electricity from solar energy.

However, if one would want to use any two or all of the above noted systems then he would have to install all of the systems alone and in its entirety, which would definitely come at a substantial cost. Additionally, the systems may also not cooperate with each other to save on installation costs. There are some designs in which engineering designers have tried to combine one or more of the above noted systems through Building Integrated Photovoltaic (BIPV) systems. In such systems solar PV and solar thermal energy collections systems are integrated within parts of the building. However, very attention has been paid on optimizing and economizing such integrations and to make the installation of such systems easier.

Thus, there is a need to provide a BIPV system that addresses at least some of the above problems.

### SUMMARY OF THE INVENTION

Disclosed herein is a building integrated solar thermal electric hybrid roofing system including a plurality of solar cell assemblies disposed on a solar exposed roof structure of a building, each of the solar cell assembly generating a DC electricity when a portion of solar energy is impacted on the solar cell assembly, the solar exposed roof structure capable of transmitting a portion of the impacted solar energy into a receiving zone of the building, a plurality of supporting members positioned at predefined locations on the roof supporting structure, each of the supporting member attachable to a corresponding solar cell assembly for supporting thereof on the solar exposed roof structure, and in a preferred embodiment, a power inverter connected to each or group of the solar cell assemblies for converting DC electricity into AC electricity.

In some embodiments, each of the solar cell assembly includes a solar cell disposed within an enclosure formed from a top transparent cover and a bottom supporting cover, the top transparent cover allows the solar energy to be impacted on a top surface of the solar cell.

In some embodiments, each of the supporting member includes an elongated spreader extending between a top mounting pin and a bottom mounting pin and positioned in a vertical orientation over the solar exposed roof structure, and wherein the bottom mounting pin is insertable within the solar exposed roof structure and rigidly attached to a bottom portion thereof and whereas the top mounting pin in insertable within the enclosure and rigidly attached to an outer portion of the top transparent cover.

In some embodiments, an insulating layer is attached to a bottom surface of solar exposed roof structure, the insulating layer preventing the portion of the solar energy to be transmitted into the receiving zone and for retaining solar thermal energy.

In some embodiments, the solar exposed roof structure is formed from a bottom supporting plate having an inner surface and a top transparent cover attached over edges of the bottom supporting plate to form an enclosure, and wherein a bottom portion of each of the solar cell assembly is fixedly attached at predefined locations on the inner surface of the bottom supporting plate.

In some embodiments, one or more edges of the solar cell assembly are glued to the bottom supporting plate at the predefined locations.

In some embodiments, the bottom supporting plate of the solar exposed roof structure is formed of an opaque material to prevent the portion of the solar energy from being transmitted within the receiving zone of a building.

In some embodiments, the solar exposed roof structure includes a transparent plate having glue attached thereto at predefined locations, and wherein each of the solar cell assembly is attached to the predefined locations on the transparent plate through the glue.

In some embodiments, the entire surface of the transparent plate includes the glue attached thereon, and wherein the plurality of solar cell assemblies is fixedly attached to the transparent plate when contacted to the glue.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description of the present embodiments of the invention and are intended to provide an overview or framework for understanding the nature and character of the invention as it is claimed. The accompanying drawings are included to provide a further understanding of the invention and are incorporated into and constitute a part of this specification. The drawings illustrate various embodiments of the invention and together with the description serve to explain the principles and operation of the invention.

### BRIEF DESCRIPTION OF THE DRAWINGS

The above-mentioned and other features and advantages of the various embodiments of the invention, and the manner of attaining them, will become more apparent and will be better understood by reference to the accompanying drawings, wherein:

FIG. 1 is a sectional elevation view of a building having an integrated solar thermal electric hybrid roofing system according to an embodiment of the present invention;

FIG. 2 is a top view of a solar exposed roof structure of the integrated solar thermal electric hybrid roofing system of FIG. 1 and having a plurality of solar cell assemblies mounted thereon;

FIG. 3 is a top view of a solar cell assembly of FIG. 2;

FIG. 4 is a cross-sectional elevation view of the solar cell assembly mounted on a supporting member and the solar exposed roof structure of FIG. 2 along the line B-B of FIG. 3 according to an embodiment of the present invention;

FIG. 5 is a sectional elevation view of the building of FIG. 1 according to another embodiment of the present invention;

FIG. 6 is a top view of the solar cell assembly of FIG. 3 having glues attached to its edges according to an embodiment of the present invention;

FIG. 7 is a sectional elevation view of the solar cell assembly of FIG. 6 attached to a bottom support plate of the solar roof structure of FIG. 5; and

FIGS. 8 and 9 show the solar cell assembly of FIG. 3 attached to the solar exposed roof structure of FIG. 1 according to another embodiment of the present invention;

FIG. 10 is a front elevation view of the solar cell assembly of FIG. 3 attached to the solar exposed roof structure of FIG. 1 according to another embodiment of the present invention.

### DETAILED DESCRIPTION OF THE PREFERRED EMBODIMENTS

Reference will now be made in detail to the exemplary embodiment(s) of the invention, as illustrated in the accompanying drawings. Whenever possible, the same reference numerals will be used throughout the drawings to refer to the same or like parts.

FIG. 1 shows a sectional elevation view of a building 100 that includes an integrated solar thermal electric hybrid roofing system 102 disposed on top 103 of the building 100, according to an embodiment of the present invention. The hybrid roofing system 102 includes a solar exposed roof structure 104 mounted on the top insulation 103 of the building 100 that defines a receiving zone 106 within the building 100 suitable for human and plant living. The solar exposed roof structure 104 receives the solar energy from the sun in day light conditions. The solar exposed roof structure 104, which is manufactured from transparent or a transparent material, transmits a portion of the received solar energy within the receiving zone 106 of the building 100 as solar thermal energy. The solar thermal energy may be used in keeping the receiving zone 106 warm. In different embodiments of the present invention, the extent of solar thermal energy transmission within the receiving zone 106 could be controlled by appropriately designing the transparency or semi transparency of the solar exposed roof structure 104. In another embodiment, the solar exposed roof structure 104 could also be made from opaque materials to prevent any solar thermal energy from being transmitted in the receiving zone 106. In another embodiment of the present invention, the solar exposed roof structure 104 could also be made from rigid materials. However, in other embodiments of the present invention, the solar exposed roof structure 104 could also be made from flexible or fabric materials. Alternatively, only predefined portions of the solar exposed roof structure 104 could be made from flexible materials. It is to be understood that all the above noted embodiments should be construed to be within the scope of the present invention.

As seen in FIG. 1, a plurality of solar cell assemblies 108 is securely positioned on the solar exposed roofing structure. A portion of the solar energy impacting the solar exposed roof structure 104 is also received by the plurality of solar cell assemblies 108, which depending on the incident angle of the impacted solar rays, converts the received solar energy into photovoltaic (PV) direct current (DC) electricity. As understood by a skilled person in the art, the DC electricity is converted into AC electricity by a power inverter (not shown) for being used for various known purposes and applications. Additionally, the generated DC or AC electric power could be sent to power grids by means known in the art.

According to an embodiment of the present invention as shown in FIG. 1, the solar exposed roof surface is designed to be oriented at an inclined position on top 103 of the building 100. Preferably, the solar exposed roof structure 104 is inclined to face the east side so that solar rays impact nearly perpendicularly on the solar exposed roof structure 104 as well on the solar cell assemblies 108. This ensures maximum utilization of the solar rays that have high energy content during the day time. However, in another embodiment of the present invention, the solar exposed roof surface may also be designed to be oriented in a horizontal position on top 103 of the building 100. Depending on the desired optimization levels, in several other embodiments, the solar exposed roof surface may also be designed to have a horizontal or a combination of inclined, horizontal and other orientations compatible with the working principle of the present invention. All the above noted embodiments should be construed to be within the scope of the present invention.

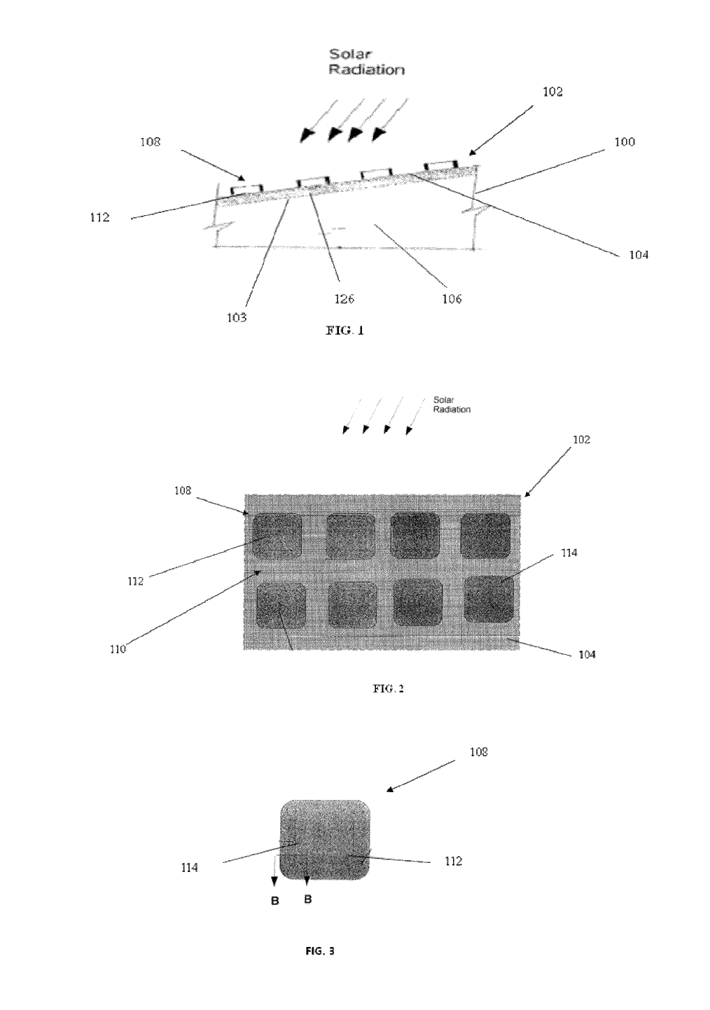

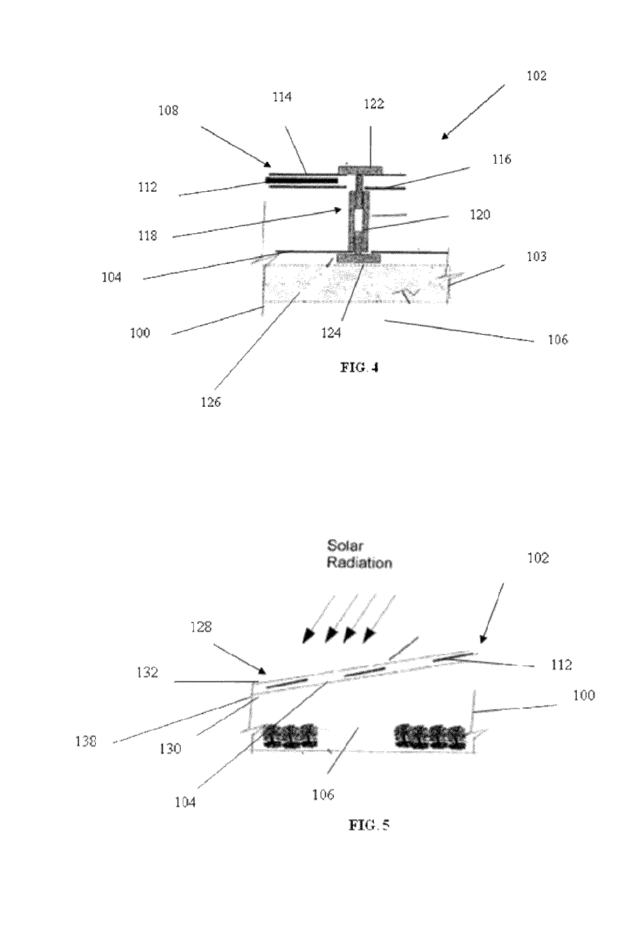

FIG. 2 shows the plurality of solar cell assemblies 108 positioned over the solar exposed roof structure 104. The solar cell assemblies 108 are positioned and preferably arranged in a grid like structure 110 over the solar exposed roof structure 104. FIGS. 3 and 4 show a top view and a cross-sectional elevation view of the solar cell assembly 108 according to an embodiment of the present invention. As seen in FIG. 4, the cross-section elevation view of the solar cell assembly 108 is taken along the lines B-B of the solar cell assembly 108 as shown in FIG. 3. In this embodiment of the solar cell assembly 108, the solar cell assembly 108 is shown to include a solar cell 112 positioned within an enclosure that is formed from a top transparent cover 114 and a bottom supporting plate 116. The top transparent cover 114 by its virtue allows a portion of the incident solar energy to be impacted on the solar cell 112 for DC electricity generation. The top transparent cover 114 could be made from any plastic or rigid materials known in the art.

FIG. 4 also shows a cross section elevation view of a supporting member 118 mounted over the solar exposed roof structure 104 and supporting the solar cell assembly 108 thereon. In a similar manner, a plurality of supporting members 118 is also positioned on the solar exposed roof structure 104 at predefined locations and supports a corresponding solar cell assembly 108 over the solar exposed roof structure 104. Preferably, each of the supporting members 118 includes an elongated spreader 120 extending between a top mounting pin 122 and a bottom mounting pin 124. Each of the supporting members 118 is positioned in a vertical orientation over the solar exposed roof structure 104. As seen in FIG. 4, the bottom mounting pin 124 of the supporting member 118 is insertable within the solar exposed roof structure 104 and rigidly attached to a bottom portion thereof. Whereas, the top mounting pin 122 of the supporting member 118 in insertable within the enclosure through the bottom supporting cover and rigidly attached to an outer portion of the top transparent cover 114. The constructional arrangement of the supporting member 118 with regard to its connection with the solar exposed roof structure 104 and the solar cell assembly 108 allows the solar cell assemblies 108 to be mounted at an elevation over the solar exposed roof structure 104. As seen in FIG. 4, the top mounting pin 122 is adjustable within the header to ensure adjustments in the elevation levels of the solar cell assemblies 108. The top mounting pin 122, the bottom mounting pin 124, the spreader 120 and the bottom supporting plate 116 could be made from any plastic, fiber reinforced plastic material or metal.

Besides supporting the solar cell assembly 108 thereon, another important advantage that each of the supporting member 118 offers is to allow airflow by natural convection between the adjacent solar cell assemblies 108 as well as between each of the solar cell assemblies 108 and the solar exposed roof structure 104, in high ambient temperature conditions. Airflow by natural convection allows the solar cell assemblies 108 to remain cooler relative to the hot ambient temperature. As such, the airflow ensures efficiency of the solar cell 112 is not adversely affected due to high ambient temperatures and the performance levels are maintained. In the embodiment where the solar exposed roof structure 104 is positioned at an inclined orientation on the top 103 of the building 100, the elevation of the solar cell assemblies 108 generates forced or natural air convection by ‘thermosiphon effect’. Due to this effect, each of the solar cell assembly 108 remains relatively cooler thereby maintaining higher solar cell efficiency and performance.

According to an embodiment of the present invention and as noted above, the solar roof structure may be designed to be opaque in a case no amount of the solar thermal energy is intended to be received within the receiving zone 106 of the building 100 (for example during peak summer conditions). Alternatively, instead of making the solar exposed roof structure 104 opaque the solar exposed roof structure 104 could be made to function as an opaque solar exposed roof structure 104. As seen in FIG. 3, such opaqueness could be achieved by positioning an insulating layer 126 adjacent to and below the solar exposed roof structure 104. The insulating layer 126 prevents any portion of the solar thermal energy from being transmitted into the receiving zone 106 of the building 100.

FIG. 5 shows another embodiment of the present invention in which instead of the solar exposed roof structure 104 being formed from a single sheet entity, the solar exposed roof structure 104 is formed of an enclosure 128 (Greenhouse Solar Roof). This enclosure 128 is formed from a transparent bottom supporting plate 130 and a top transparent cover 132 attached all over edges of the bottom supporting plate 130, encasing solar cell 112. Preferably, the bottom supporting plate 130 is formed from any fabric, plastic, plastics reinforced by fiberglass strands, or other fiber strands material, which is either transparent or semi-transparent. Such bottom supporting plate 130 allows transmission of the portion of the solar thermal energy into the receiving zone 106 of the building 100 when the solar energy impacts the solar exposed roof structure 104. Such type of the solar exposed roof structure 104 may be used for Greenhouse applications well known in the art, especially for Greenhouse plants. In embodiments, where the bottom supporting plate 130 is semi-transparent, the portion of the solar rays passing there through will be in the form of diffuse light.

As seen in FIG. 5, the bottom supporting plate 130 has an inner surface 134 on which, and at predefined locations, a bottom portion of each of the solar cell 112 is rigidly attached. So, by way of this arrangement, both the PV DC electricity as well as the solar thermal energy, as noted above, would be generated. The solar thermal energy generated in this case would be used for Greenhouse applications. However, in other embodiments if no solar thermal energy is required then the transparent bottom supporting plate 130 could be replaced with an opaque plate or the transparent bottom supporting plate 130 could be used in combination with the insulating layer 126. All such embodiments should be construed to be within the scope of the present invention.

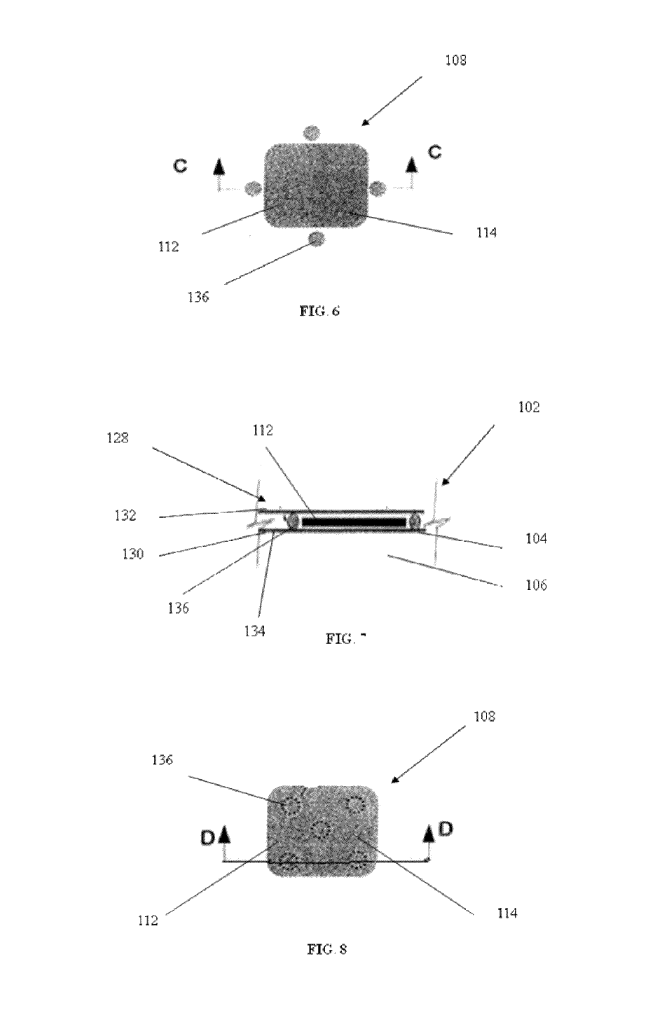

FIGS. 6 and 7 show an embodiment of the present invention in which the solar cells 112 are attached to the inner surface 134 of bottom supporting plate 130 by the usage of another form of supporting member 118, for example glue 136. Preferably, the glue 136 is applied on one or more edges 138 of each of the solar cells 112 and then attached on the inner surface 134 of the bottom supporting plate 130 at predefined locations. The glue 136 provides rigid attachment of the solar cells 112 on the solar exposed roof structure 104.

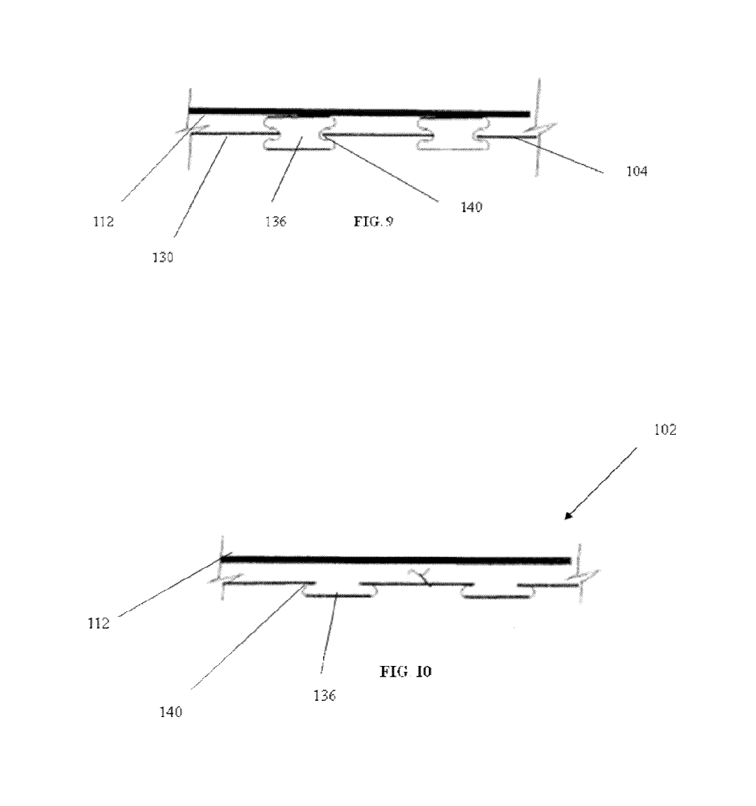

FIGS. 8 and 9 show another embodiment of the present invention in which the solar exposed roof structure 104 is essentially a single transparent plate. Preferably, at several predefined locations 140 on the transparent plate glue 136 is applied in spots and in selective groups. On each of these selective groups of glue 136 the bottom portion of the solar cell 112 is attached to ensure rigid attachment between the solar cells 112 and the transparent plate. A skilled person in the art would understand from this embodiment that while the single transparent plate would allow the portion of the solar rays to be transmitted within the receiving zone 106 of the green house area, the plurality of solar cell 112 generate PV DC electricity. As such, even in this embodiment, both the PV DC electricity as well as the solar thermal energy, as noted above, is generated. Further, as noted above, the electric power generated by the solar cells 112 could be transmitted through wires or could be utilized for home or business applications. Additionally, the electric power could also be sent to power grid by means known in the art.

FIG. 10 shows another method of rigidly attaching the plurality of solar cells 112 on the single transparent plate as noted above. In this embodiment instead of the glue 136 being applied in spots and in selective groups, the glue 136 is applied all over the single transparent plate. On the glue 136 the plurality of solar cells 112 are then affixed.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

What is claimed is:

1. A building integrated solar thermal and electric hybrid roofing system comprising:
a plurality of solar cell assemblies disposed on a solar exposed roof structure of a building, each of the solar cell assembly generating a DC electricity when a portion of solar energy is impacted on the solar cell assembly, the solar exposed roof structure capable of transmitting a portion of the impacted solar energy into a receiving zone of the building;
a plurality of supporting members positioned at predefined locations on the roof supporting structure, each of the supporting member attachable to a corresponding solar cell assembly for supporting thereof on the solar exposed roof structure.

2. The system according to claim 1, wherein each of the solar cell assembly includes a solar cell disposed within an enclosure formed from a top transparent cover and a bottom supporting cover, the top transparent cover allows the solar energy to be impacted on a top surface of the solar cell.

3. The system according to claim 2, wherein each of the supporting member includes an elongated spreader extending between a top mounting pin and a bottom mounting pin and positioned in a vertical orientation over the solar exposed roof structure, and wherein the bottom mounting pin is insertable within the solar exposed roof structure and rigidly attached to a bottom portion thereof and whereas the top mounting pin in insertable within the enclosure and rigidly attached to an outer portion of the top transparent cover.

4. The system according to claim 1, wherein the solar exposed roof structure is formed from a material that is either transparent or semi-transparent for transmitting the portion of the solar energy into the receiving zone of the building when impacted by the solar energy.

5. The system according to claim 4, wherein an insulating layer is attached to a bottom surface of solar exposed roof structure, the insulating layer preventing the portion of the solar energy to be transmitted into the receiving zone.

6. The system according to claim 1, wherein the solar exposed roof structure is formed from a material that is opaque, the opaque solar exposed roof structure preventing the portion of the solar energy from penetrating within the receiving zone of the building.

7. The system according to claim 1, wherein the solar exposed roof structure is formed from a bottom supporting plate having an inner surface and a top transparent cover attached over edges of the bottom supporting plate to form an enclosure, and wherein a bottom portion of each of the solar cell assembly is fixedly attached at predefined locations on the inner surface of the bottom supporting plate.

8. The system according to claim 7, wherein one or more edges of the solar cell assembly are glued to the bottom supporting plate at the predefined locations.

9. The system according to claim 7, wherein the bottom supporting plate is formed from a material that is either transparent or semi-transparent for transmitting the portion of the solar energy into the receiving zone of the building when the solar energy impacts the solar exposed roof structure.

10. The system according to claim 7, wherein the bottom supporting plate of the solar exposed roof structure is formed of an opaque material to prevent the portion of the solar energy from being transmitted within the receiving zone of a building.

11. The system according to claim 1, wherein the solar exposed roof structure includes a transparent plate having glue attached thereto at predefined locations, and wherein each of the solar cell assembly is attached to the predefined locations on the transparent plate through the glue.

12. The system according to claim 11, wherein the entire surface of the transparent plate includes the glue attached thereon, and wherein the plurality of solar cell assemblies is fixedly attached to the transparent plate when contacted to the glue.

13. The system according to claim 1, wherein the plurality of solar cell assemblies are arranged in grid structure and disposed on the solar exposed roof structure of the building, and wherein predetermined parts of the roof structure are made from flexible materials.

14. The system according to claim 1, a power inverter connected to each or group of the solar cell assemblies for converting DC electricity into AC electricity.
